(19) United States
(12) Patent Application Publication
(10) Pub. No.: US 2025/0338776 A1
(43) Pub. Date: Oct. 30, 2025

(54) MAGNETORESISTIVE RANDOM ACCESS MEMORY AND METHOD FOR FABRICATING THE SAME

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 18/746,087

(22) Filed: Jun. 18, 2024

(30) Foreign Application Priority Data
Apr. 29, 2024 (TW) 113115881

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A method for fabricating a magnetoresistive random access memory (MRAM) device includes the steps of first forming a spin orbit torque (SOT) layer on a substrate, forming a magnetic tunneling junction (MTJ) on the SOT layer, forming a first cap layer adjacent to the MTJ, and then forming a second cap layer adjacent to the first cap layer. Preferably, a thickness of the first cap layer is greater than a thickness of the second cap layer.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes the steps of first forming a spin orbit torque (SOT) layer on a substrate, forming a magnetic tunneling junction (MTJ) on the SOT layer, forming a first cap layer adjacent to the MTJ, and then forming a second cap layer adjacent to the first cap layer. Preferably, a thickness of the first cap layer is greater than a thickness of the second cap layer.

According to another aspect of the present invention, a magnetoresistive random access memory (MRAM) device includes a spin orbit torque (SOT) layer on a substrate, a magnetic tunneling junction (MTJ) on the SOT layer; a first cap layer adjacent to the MTJ, and a second cap layer adjacent to the first cap layer. Preferably, a thickness of the first cap layer is greater than a thickness of the second cap layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a MRAM device according to an embodiment of the present invention.

### DETAILED DESCRIPTION

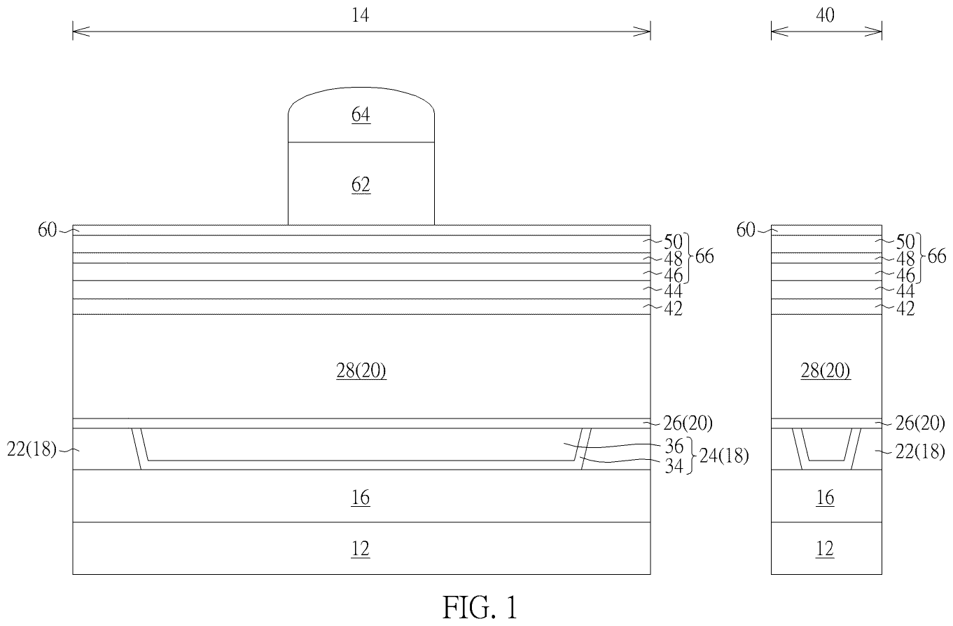

Referring to FIGS. 1-9, FIGS. 1-9 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region 40 are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections (not shown) embedded in the stop layer 26 and the IMD layer 28.

In this embodiment, each of the metal interconnections 24 from the metal interconnect structure 18 preferably includes a trench conductor and each of the metal interconnections (not shown) from the metal interconnect structure 20 includes a via conductor. Preferably, each of the metal interconnections 24 from the metal interconnect structures 18, 20 could be embedded within the IMD layers 22, 28 and/or stop layer 26 according to a single damascene process or dual damascene process. For instance, each of the metal interconnections 24 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, a selective bottom electrode 42, a spin orbit torque (SOT) layer 44, a MTJ stack 66, a cap layer 60, and a patterned mask or top electrode (TE) 62 are formed on the metal interconnect structure 20. In this embodiment, the formation of the MTJ stack 66 could be accomplished by sequentially depositing a free layer 46, a barrier layer 48, a reference layer (not shown), a spacer (not shown), and a pinned layer 50 on the SOT layer 44. Preferably, the free layer 46 could be made of ferromagnetic material including but not limited to for example iron, cobalt, nickel, or alloys thereof such as cobalt-iron-boron (CoFeB), in which the magnetized direction of the free layer 46 could be altered freely depending on the influence of outside magnetic field. The barrier layer 48 could be made of insulating material including but not limited to for example oxides such as aluminum oxide (AlOₓ) or magnesium oxide (MgO).

The reference layer is disposed between the barrier layer 48 and the spacer, in which the reference layer could be made of ferromagnetic material including but not limited to for example iron, cobalt, nickel, or alloys thereof such as cobalt-iron-boron (CoFeB). The spacer could be a non-magnetic layer made of non-magnetic material including but not limited to for example ruthenium (Ru), iridium (Ir), rhodium (Rh), or combination thereof.

The pinned layer 50 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 50 is formed to fix or limit the direction of magnetic moment of adjacent layers. Specifically, the pinned layer 50 further includes a bottom synthetic antiferromagnetic (SAF) layer, a coupling layer, and a top SAF layer, in which the bottom SAF layer and the top SAF layer could include same or different materials while both layers could include ferromagnetic material such as cobalt (Co), nickel (Ni), platinum (Pt), palladium (Pd), or combination thereof. The coupling layer may also include materials to provide mechanical and/or crystalline structural support for the bottom SAF layer and the top SAF layer. Preferably, the coupling layer includes material that aides in this coupling including but not limited to ruthenium (Ru), tantalum (Ta), gadolinium (Gd), platinum (Pt), hafnium (Hf), or combination thereof.

Moreover, the selective bottom electrode 42 could include conductive material such as but not limited to for example Ta, TaN, Pt, Cu, Au, Al, or combination thereof, the SOT layer 44 is serving as a channel for the MRAM device as the SOT layer 44 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ru, and the TE 62 preferably includes conductive or dielectric material such as tantalum (Ta), tantalum nitride (TaN), titanium (Ti), titanium nitride (TiN), platinum (Pt), copper (Cu), gold (Au), aluminum (Al), or combination thereof.

In this embodiment, the formation of the patterned TE 62 could be accomplished by first forming a dielectric layer 64 made of silicon oxide on an un-patterned TE 62 and then using a patterned mask (not shown) such as patterned resist as mask to remove part of the dielectric layer 64 and part of the TE 62 through reactive ion etching (RIE) process for forming a patterned dielectric layer 64 and a patterned TE 62. The dielectric layer 64 made of silicon oxide could be selectively removed thereafter.

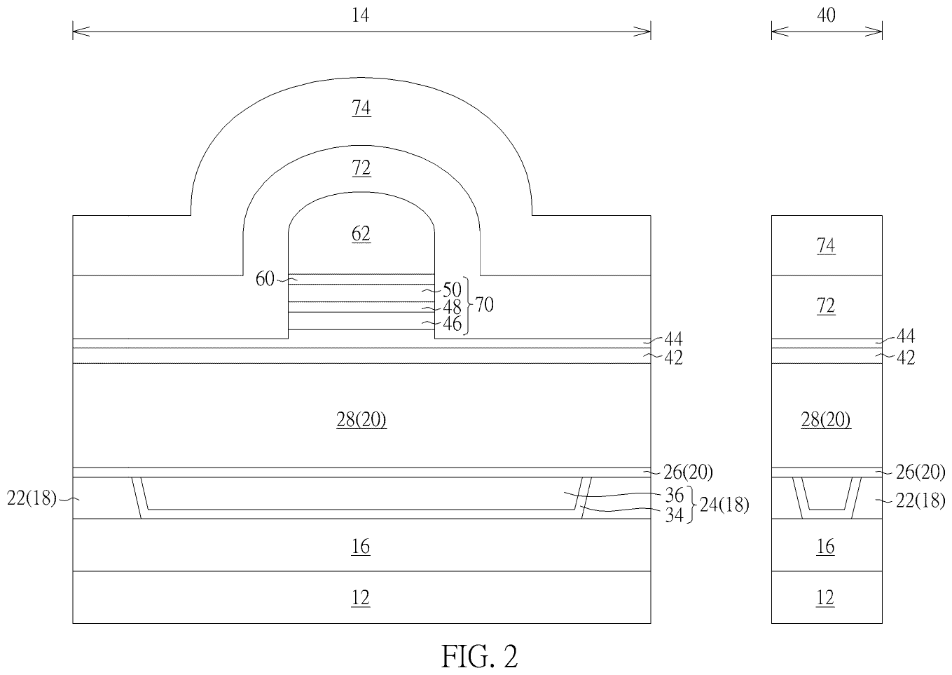

Next, as shown in FIG. 2, the patterned dielectric layer 64 or the patterned TE 62 could be used as a mask to remove part of the cap layer 60, part of the MTJ stack 66, and even part of the SOT layer 44 for forming a MTJ 70, and then a first cap layer 72 is formed on the MTJ 70 and an inter-metal dielectric (IMD) layer 74 is formed on the first cap layer 72. Preferably, the MTJ stack 66 on the logic region 40 is completely removed at this stage and during the aforementioned patterning process, parameters of the etching process are adjusted so that the top surface of the TE 62 directly on top of the MTJ 70 would form a curved surface. In this embodiment, the first cap layer 72 is preferably made of silicon nitride while the IMD layer 74 is made of silicon oxide or tetraethoxysilane (TEOS). It should be noted that when the patterned TE 62 is used to pattern the MTJ stack 66 for forming the MTJ 70, part of the SOT layer 44 could be removed at the same time so that the top surface of the remaining SOT layer 44 adjacent to two sides of the MTJ 70 is slightly lower than the top surface of the SOT layer 44 directly under the MTJ 70. According to an embodiment of the present invention, if none of the SOT layer 44 were removed during the formation of the MTJ 70, the top surface of the SOT layer 44 adjacent to two sides of the MTJ 70 would be even with the top surface of the SOT layer 44 directly under the MTJ 70. Moreover, the first cap layer 72 and the IMD layer 74 formed at this stage are preferably disposed on the MRAM region 14 and the logic region 40 at the same time.

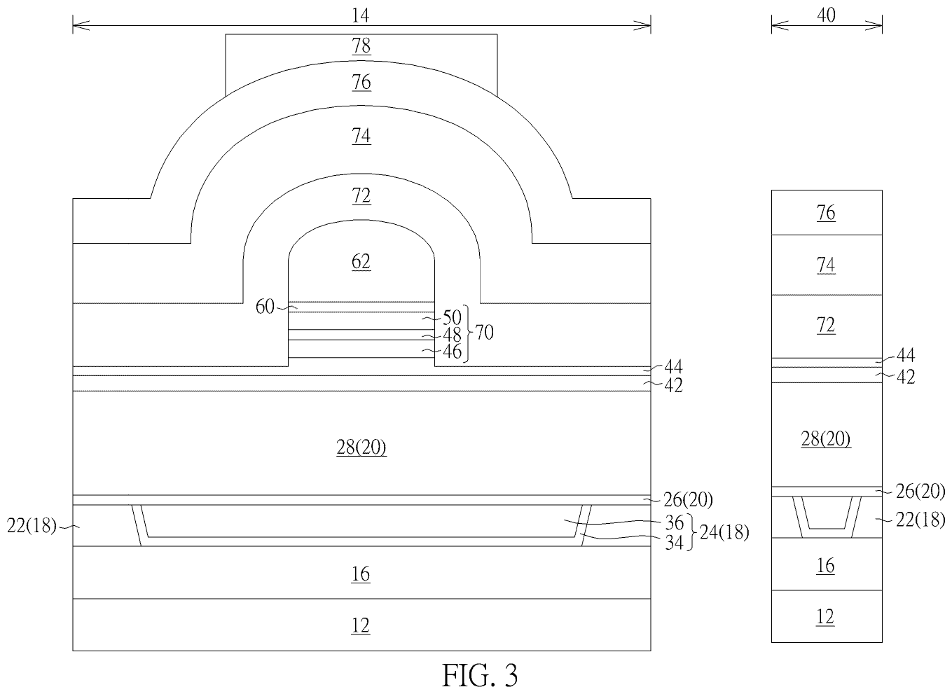

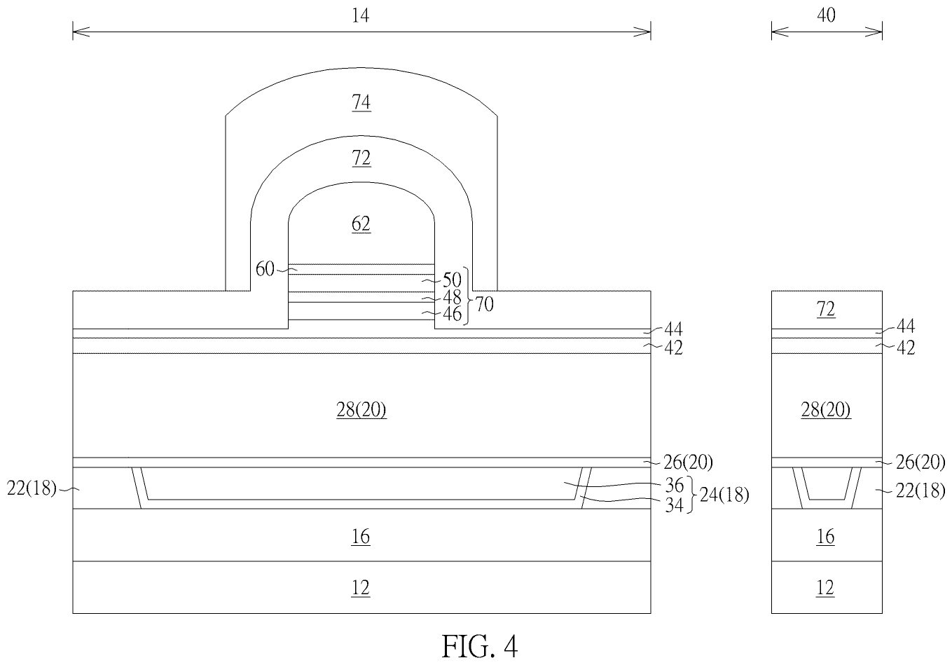

Next, as shown in FIGS. 3-4, a bottom anti-reflective coating (BARC) 76 is formed on the IMD layer 74, and then an etching process such as an ion beam etching (IBE) process is conducted by using a patterned mask 78 such as a patterned resist as mask to remove part of the BARC 76 and part of the IMD layer 74 on the MRAM region 14 and all of the BARC 76 and IMD layer 74 on the logic region 40 for exposing the surface of the first cap layer 72 underneath. Preferably, the remaining IMD layer 74 is only disposed on the MRAM region 14 while the first cap layer 72 underneath is still disposed on the MRAM region 14 and the logic region 40. The BATC 76 is then removed to expose the IMD layer 74 on the MRAM region 14.

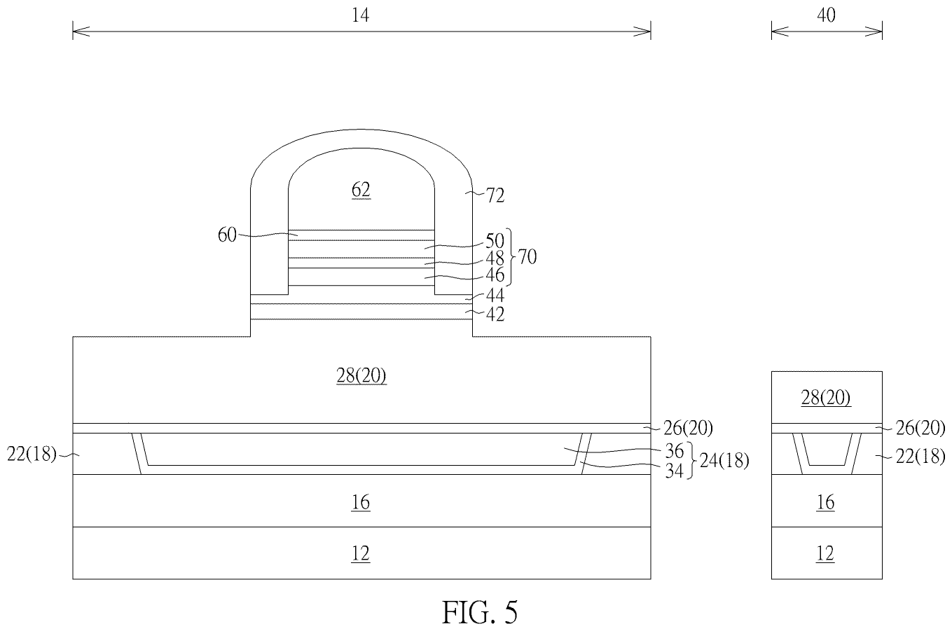

Next, as shown in FIG. 5, an etching process such as an IBE process is conducted without forming other patterned mask to remove all of the IMD layer 74, part of the first cap layer 72, part of the SOT layer 44, part of the bottom electrode 42, and even part of the IMD layer 28 on the MRAM region 14 and all the first cap layer 72, all the SOT layer 44, all of the bottom electrode 42, and part of the IMD layer 28 on the logic region 40. This reduces the width of the first cap layer 72, the SOT layer 44, the bottom electrode 42, and part of the IMD layer 28 on the MRAM region 14 so that the left and right sidewalls of the first cap layer 72, the SOT layer 44, the bottom electrode 42, and part of the IMD layer 28 are retracted inward and aligned with each other. The top surface of the remaining IMD layer 28 on the logic region 40 on the other hand could be slightly lower than the top surface of the IMD layer 28 on the MRAM region 14.

It should be noted that even though the IBE process conducted at this stage removes part of the IMD layer 28 during the patterning of the first cap layer 72, the SOT layer 44, and the bottom electrode 42, according to other embodiment of the present invention, it would also be desirable to not removing any of the IMD layer 28 during the patterning of the first cap layer 72, the SOT layer 44, and the bottom electrode 42. In this instance, after the first cap layer 72, the SOT layer 44, and the bottom electrode 42 are patterned, the top surface of the IMD layer 28 adjacent to two sides of the first cap layer 72 or SOT layer 44 is even with the top surface of the IMD layer 28 directly under the MTJ 70, which is also within the scope of the present invention.

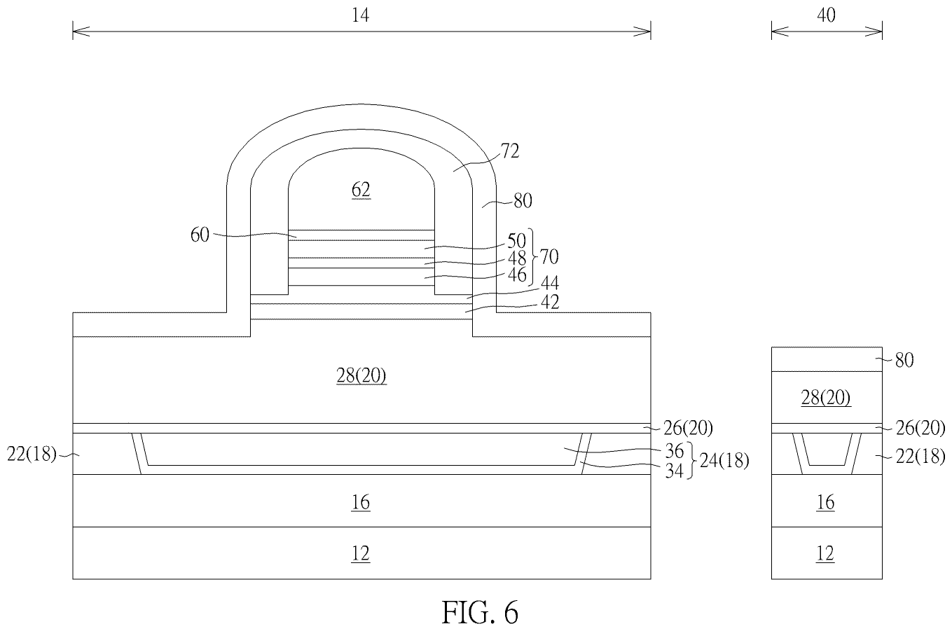

Next, as shown in FIG. 6, a second cap layer 80 is formed on the first cap layer 72 and the IMD layer 28, in which the second cap layer 80 preferably covers the top surface of the first cap layer 72, sidewalls of the first cap layer 72, sidewalls of the SOT layer 44, sidewalls of the bottom electrode 42, and the top surface of the IMD layer 28. In this embodiment, the first cap layer 72 and the second cap layer 80 are preferably made of same material such as silicon nitride (SiN).

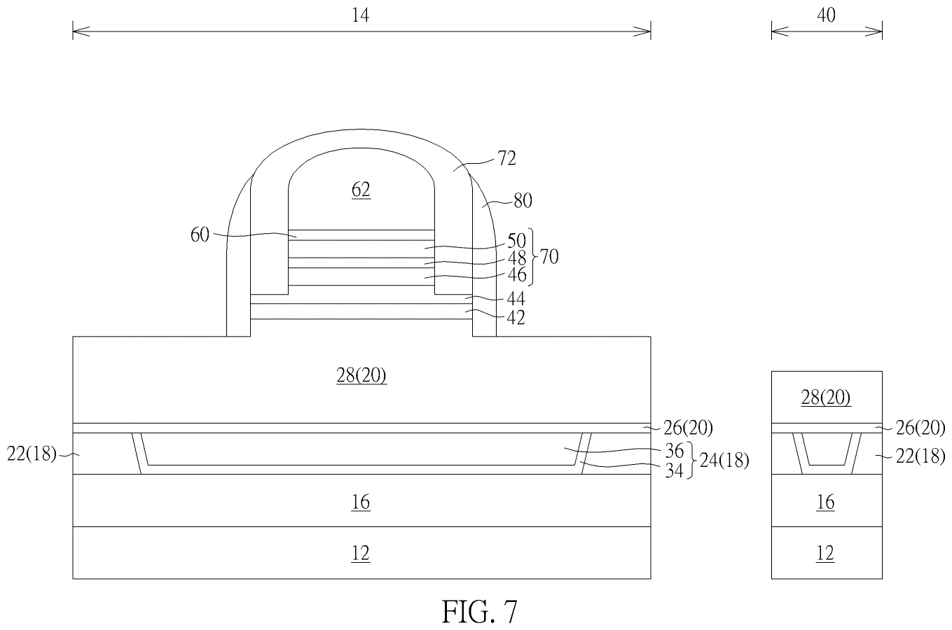

Next, as shown in FIG. 7, an etching process could be conducted without forming any patterned mask to remove part of the second cap layer 80 on the MRAM region 14 and all the second cap layer 80 on the logic region 40 and expose the top surface of the IMD layer 28. Preferably, the curved top surface of the second cap layer 80 adjacent to sidewalls of the first cap layer 72 is aligned with the curved top surface of the first cap layer 72 or the curved top surface of the first cap layer 72 is extended continuously to the curved top surface of the second cap layer 80.

In this embodiment, the thickness of the first cap layer 72 is greater than the thickness of the second cap layer 80, in which the definition of thickness could be defined as the maximum distance or maximum width of each of the first cap layer 72 and second cap layer 80 extending along the X-direction. According to an embodiment of the present invention, the thickness of the second cap layer 80 is approximately 40%-80% or most preferably 60% of the thickness of the first cap layer 72. Moreover, even though both the first cap layer 72 and the second cap layer 80 are made of silicon nitride, the silicon concentration in the first cap layer 72 is preferably greater than the silicon concentration in the second cap layer 80 and the refractive index ratio of the first cap layer 72 to the second cap layer 80 is between 1.2 to 1.7. By using this recipe for adjusting the thickness as well as refractive index between the first cap layer 72 and the second cap layer 80, it would be desirable to fill more IMD layer adjacent to the MTJ in the later process thereby improving insulation capability for the device.

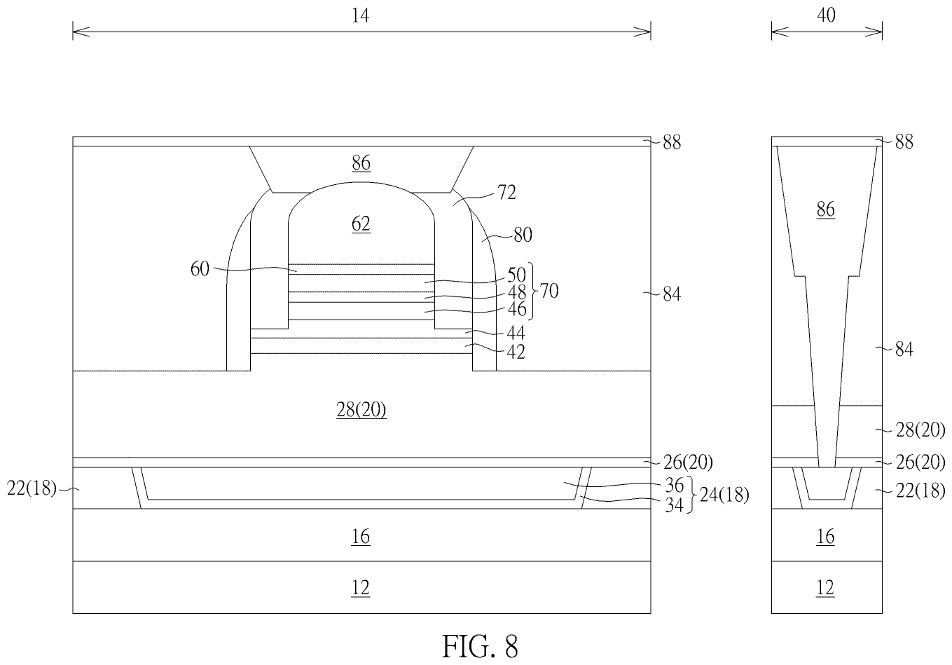

Next, as shown in FIG. 8, another IMD layer 84 is formed on the MRAM region 14 and logic region 40, a planarizing process such as chemical mechanical polishing (CMP) is conducted to remove part of the IMD layer 84, and then a pattern transfer process is conducted by using a patterned mask (not shown) to remove part of the IMD layer 84 and part of the first cap layer 72 on the MRAM region 14 and part of the IMD layer 84, part of the IMD layer 28, and part of the stop layer 26 on the logic region 40 to form contact holes (not shown) exposing the TE 62 and the metal interconnection 24 underneath and conductive materials are deposited into the contact holes afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form metal interconnections 86 in the contact holes electrically connecting the TE 62 and the metal interconnection 24. Next, a stop layer 88 is formed on the metal interconnections 86. In this embodiment, the IMD layer 84 and the IMD layer 74 could be made of same or different material such as silicon oxide and the stop layer 88 could include silicon oxide, silicon nitride, or SiCN.

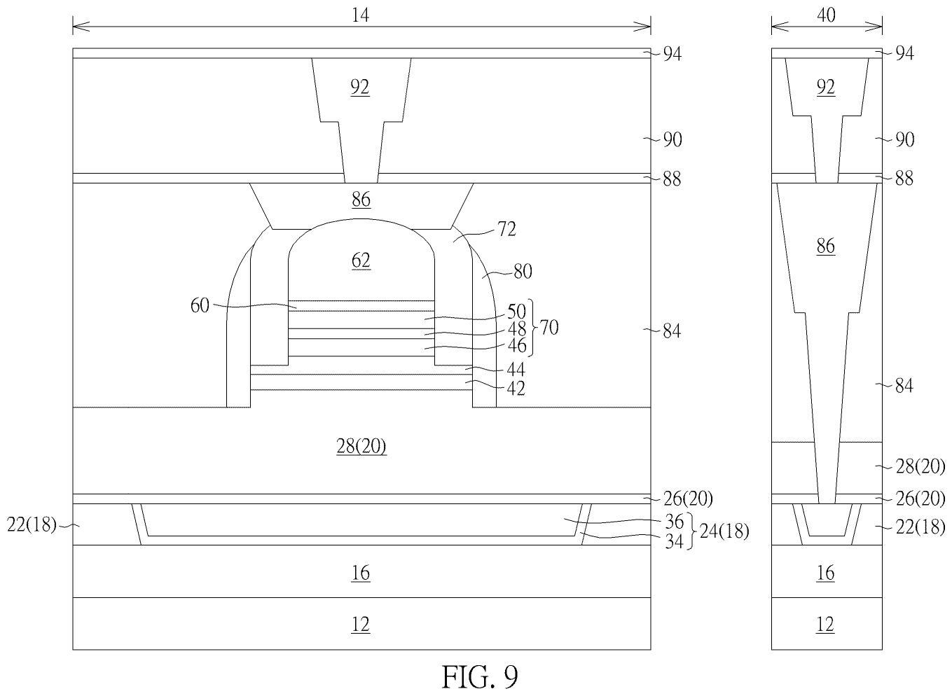

Next, as shown in FIG. 9, an IMD layer 90 is formed on the stop layer 88 of the MRAM region 14 and logic region 40, and a pattern transfer process is conducted by using a patterned mask (not shown) to remove part of the IMD layer 90 and part of the stop layer 88 for forming contact holes (not shown) exposing the metal interconnections 86 and conductive materials are deposited into the contact hole afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form metal interconnections 92 in the contact holes electrically connecting the metal interconnections 86. Next, a stop layer 94 is formed on the metal interconnection 92. In this embodiment, the IMD layer 90 preferably includes an ultra low-k (ULK) dielectric layer including but not limited to for example porous material or silicon oxycarbide (SiOC) or carbon doped silicon oxide (SiOCH).

Overall, the present invention discloses a method for fabricating SOT MRAM device and relating structure thereof, which first forms a SOT layer 44 and MTJ 70 on a substrate, forms a first cap layer 72 adjacent to the MTJ, and then forms a second cap layer 80 adjacent to the first cap layer, in which the thickness of the first cap layer 72 is greater than the thickness of the second cap layer 80, the top surfaces of the first cap layer 72 and the second cap layer 80 both include curves or curved surfaces, the curved top surface of the first cap layer 72 is higher than the curved top surface of the second cap layer 80, the curved top surface of the first cap layer 72 extends continuously to the curved top surface of the second cap layer 80, the first cap layer 72 and the second cap layer 80 are both made of SiN while the silicon concentration of the first cap layer 72 is greater than the silicon concentration of the second cap layer 80, and the refractive index ratio of the first cap layer 72 to the second cap layer 80 is between 1.2 to 1.7. By using the above parameters for adjusting thickness and refractive index between the first cap layer 72 and the second cap layer 80, it would be desirable to fill more IMD layer adjacent to the MTJ in the later process thereby improving insulation capability for the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a magnetoresistive random access memory (MRAM) device, comprising:
forming a spin orbit torque (SOT) layer on a substrate;
forming a magnetic tunneling junction (MTJ) on the SOT layer;
forming a first cap layer adjacent to the MTJ; and
forming a second cap layer adjacent to the first cap layer, wherein a thickness of the first cap layer is greater than a thickness of the second cap layer.

2. The method of claim 1, further comprising:
forming a top electrode (TE) on the MTJ;
forming the first cap layer on the MTJ and the SOT layer;
performing a first etching process to pattern the first cap layer;
forming the second cap layer on the first cap layer;
performing a second etching process to pattern the second cap layer; and
forming an inter-metal dielectric (IMD) layer on the first cap layer and the second cap layer.

3. The method of claim 2, wherein a top surface of the TE comprises a curve.

4. The method of claim 1, wherein a width of the MTJ is less than a width of the SOT layer.

5. The method of claim 1, wherein a bottom surface of the second cap layer is lower than a bottom surface of the first cap layer.

6. The method of claim 1, wherein a silicon concentration in the first cap layer is greater than a silicon concentration in the second cap layer.

7. A magnetoresistive random access memory (MRAM) device, comprising:
a spin orbit torque (SOT) layer on a substrate;
a magnetic tunneling junction (MTJ) on the SOT layer;
a first cap layer adjacent to the MTJ; and
a second cap layer adjacent to the first cap layer, wherein a thickness of the first cap layer is greater than a thickness of the second cap layer.

8. The MRAM device of claim 7, further comprising:
a top electrode (TE) on the MTJ; and
an inter-metal dielectric (IMD) layer around the second cap layer.

9. The MRAM device of claim 8, wherein a top surface of the TE comprises a curve.

10. The MRAM device of claim 7, wherein a width of the MTJ is less than a width of the SOT layer.

11. The MRAM device of claim 7, wherein a bottom surface of the second cap layer is lower than a bottom surface of the first cap layer.

12. The MRAM device of claim 7, wherein a silicon concentration in the first cap layer is greater than a silicon concentration in the second cap layer.
